(19) United States
(12) Patent Application Publication
(10) Pub. No.: US 2022/0266415 A1
(43) Pub. Date: Aug. 25, 2022

(54) SUBSTRATE POLISHING APPARATUS

(71) Applicant: KCTECH CO., LTD., Gyeonggi-do (KR)

(72) Inventors: Sung Ho SHIN, Gyeonggi-do (KR); Geun Sik YUN, Gyeonggi-do (KR); Hee Cheul JUNG, Seoul (KR); Tae Hyeon KIM, Gyeonggi-do (KR); Kang Jae LEE, Gyeonggi-do (KR); Jin Su BAE, Gyeonggi-do (KR); Sun Su KIM, Gyeonggi-do (KR)

(73) Assignee: KCTECH CO., LTD., Gyeonggi-do (KR)

(21) Appl. No.: 17/679,110

(22) Filed: Feb. 24, 2022

(30) Foreign Application Priority Data
Feb. 25, 2021 (KR) 10-2021-0025720

(51) Int. Cl. B24B 37/015; B24B 57/02

(52) U.S. Cl. CPC B24B 37/015; B24B 57/02

(57) ABSTRACT

A substrate polishing apparatus according to an example embodiment may include a substrate carrier configured to grasp and move a substrate, a polishing pad configured to come into contact with a polishing target surface of the substrate and polish the polishing target surface of the substrate, and a spray unit including a spray member configured to spray a fluid toward the substrate carrier.

### CROSS-REFERENCE TO RELATED APPLICATION

This application claims the benefit of Korean Patent Application No. 10-2021-0025720 filed on Feb. 25, 2021, in the Korean Intellectual Property Office, the entire disclosure of which is incorporated herein by reference for all purposes.

### BACKGROUND

### 1. Field of the Invention

One or more example embodiments relate to a substrate polishing apparatus.

### 2. Description of the Related Art

Chemical mechanical polishing (CMP) including polishing, buffing, and cleaning is needed to manufacture a semiconductor element. The semiconductor element has a multilayer structure, and a transistor element having a diffusion region is formed on a substrate layer. Connection metal lines are patterned on the substrate layer and electrically connected to a transistor element having a functional element. As publicly known, a patterned conductive layer is insulated from another conductive layer by an insulating material made of silicon dioxide. Because the semiconductor element has many metal layers and insulating layers related thereto, there is an increasing need to flatten the insulating material. If the insulating material is not flattened, the surface of the substrate irregularly changes in shape, which makes it substantially difficult to manufacture an additional metal layer. In addition, a metal line pattern is made of an insulating material, and a metal CMP process removes excessive metal materials.

The CMP process includes a process of physically abrading the surface of the substrate by using a polishing pad. This process is performed by grasping the substrate with a substrate carrier and pressing the substrate against a polishing head. In general, because the polishing pad has elasticity, the pressing force applied to the substrate is not uniform during the polishing process, which causes the substrate to separate from the carrier head. Therefore, the substrate carrier has a retainer ring configured to support an edge region of the substrate.

Meanwhile, during the polishing process, the retainer ring comes into contact with the polishing pad and generates friction with the polishing pad, which generates heat from the retainer ring. When the frictional heat is generated, the amount of abrasion of the retainer ring increases in a high-temperature section. The retainer ring is a member that is periodically replaced when the retainer ring is abraded during the polishing process. When the amount of abrasion is increased by frictional heat, a replacement cycle for the retainer ring is shortened, which may cause an economic loss. Accordingly, there is a need for an apparatus capable of maintaining a temperature of the retainer ring within a predetermined range by reducing the temperature of the retainer ring.

The above-mentioned background art is technical information that the inventors have retained to derive the contents disclosed in the present application or have obtained in the course of deriving the contents disclosed in the present application, and cannot be thus said to be technical information publicly known to the public before filing the present application.

### SUMMARY

Example embodiments provide a substrate polishing apparatus capable of maintaining a constant temperature of a substrate carrier by spraying a fluid toward the substrate carrier.

According to an aspect, there is provided a substrate polishing apparatus including: a substrate carrier configured to grasp and move a substrate; a polishing pad configured to come into contact with a polishing target surface of the substrate and polish the polishing target surface of the substrate; and a spray unit including a spray member configured to spray a fluid toward the substrate carrier.

The substrate carrier may include: a carrier head configured to adjust a position of the substrate; a membrane connected to the carrier head and configured to define a pressure chamber for applying a pressure to the substrate; and a retainer ring connected to the carrier head and configured to grasp the substrate.

The spray member may spray the fluid toward the retainer ring.

The spray member may spray the fluid toward a lateral side of the retainer ring in a direction parallel to an upper surface of the polishing pad.

The spray member may spray the fluid toward a lateral side of the retainer ring at an angle of 30 degrees to 60 degrees with respect to a ground surface.

The spray member may spray the fluid toward the retainer ring, such that a surface temperature of the retainer ring is maintained within a predetermined range.

The spray unit may further include: a spray body disposed at one side of the substrate carrier and positioned above the polishing pad; and a rotary member configured to rotate the spray body about a rotation axis.

The spray member may be positioned at a lateral side of the spray body and face the substrate carrier.

The spray unit may further include a slurry supply member connected to the spray body and configured to spray slurry toward the polishing pad.

The substrate polishing apparatus may further include: a temperature sensor configured to detect a change in temperature of the substrate carrier; and a control unit configured to adjust an operation of the spray unit on the basis of information on a temperature detected by the temperature sensor.

The spray unit may further include a leak sensor configured to detect a degree to which the fluid is sprayed.

The control unit may adjust the amount of fluid to be sprayed by the spray unit on the basis of spray information of the spray unit detected by the leak sensor.

The substrate polishing apparatus may further include a warning unit configured to generate a warning signal when a value of a temperature of the substrate carrier detected by the temperature sensor exceeds a reference danger range.

Additional aspects of example embodiments will be set forth in part in the description which follows and, in part, will be apparent from the description, or may be learned by practice of the disclosure.

According to the substrate polishing apparatus according to the example embodiment, it is possible to constantly maintain the temperature of the substrate carrier by spraying the fluid toward the substrate carrier, thereby reducing the abrasion rate of the substrate carrier and lengthening the replacement cycle.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a perspective view of a substrate polishing apparatus according to the example embodiment;

FIG. 2 is a cross-sectional view illustrating an interior of a substrate carrier according to the example embodiment;

FIG. 3 is a top plan view of the substrate polishing apparatus according to the example embodiment;

FIG. 4 is a side view of the substrate polishing apparatus according to the example embodiment; and

FIG. 5 is a block diagram of the substrate polishing apparatus according to the example embodiment.

### DETAILED DESCRIPTION

Hereinafter, example embodiments will be described in detail with reference to the accompanying drawings. However, the example embodiments may be variously modified, and the protection scope of the patent application is not restricted or limited by the example embodiments. It should be understood that all alterations, equivalents, and alternatives of the example embodiments belong to the protection scope.

The terms used in the example embodiments are used for the purpose of describing the example embodiments, and the terms should not be construed as limiting the present disclosure. Singular expressions include plural expressions unless clearly described as different meanings in the context. In the present specification, the terms “comprises,” “comprising,” “includes,” “including,” “containing,” “has,” “having” or other variations thereof are inclusive and therefore specify the presence of stated features, integers, steps, operations, elements, components, and/or combinations thereof, but do not preclude the presence or addition of one or more other features, integers, steps, operations, elements, components, and/or combinations thereof.

Unless otherwise defined, all terms used herein, including technical or scientific terms, have the same meaning as commonly understood by those skilled in the art to which the example embodiment pertains. The terms such as those defined in a commonly used dictionary should be interpreted as having meanings consistent with meanings in the context of related technologies and should not be interpreted as ideal or excessively formal meanings unless explicitly defined in the present application.

In addition, in the description of the example embodiments with reference to the accompanying drawings, the same constituent elements will be designated by the same reference numerals regardless of reference numerals, and a duplicated description thereof will be omitted. In the description of the example embodiment, the specific descriptions of publicly known related technologies will be omitted when it is determined that the specific descriptions may unnecessarily obscure the subject matter of the example embodiment.

In addition, the terms first, second, A, B, (a), and (b) may be used to describe constituent elements of the example embodiments. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The constituent element, which has the same common function as the constituent element included in any one example embodiment, will be described by using the same name in other example embodiments. Unless disclosed to the contrary, the configuration disclosed in any one example embodiment may be applied to other example embodiments, and the specific description of the repeated configuration will be omitted.

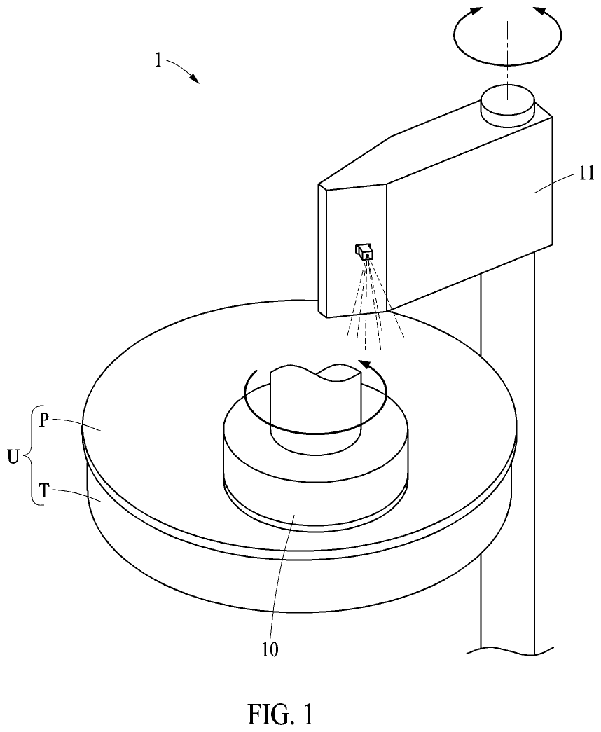

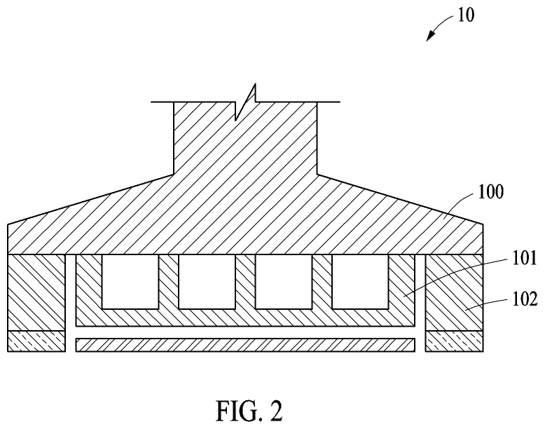

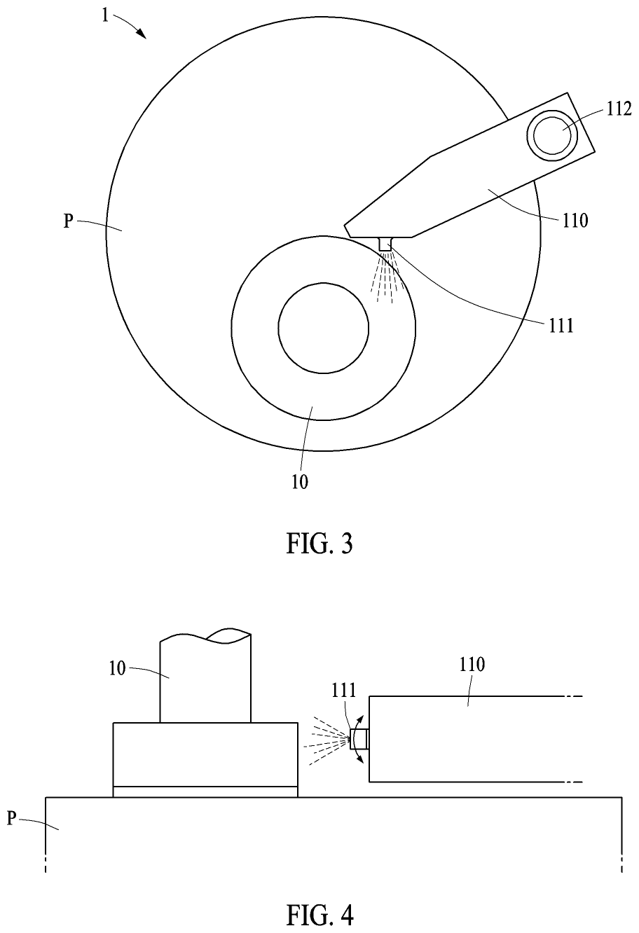

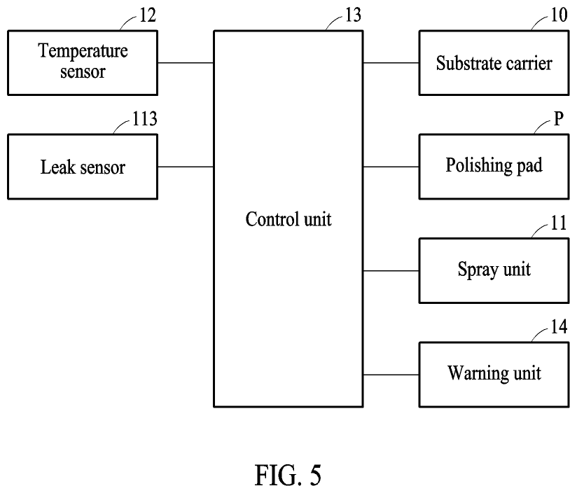

FIG. 1 is a perspective view of a substrate polishing apparatus according to the example embodiment, FIG. 2 is a cross-sectional view illustrating an interior of a substrate carrier according to the example embodiment, FIG. 3 is a top plan view of the substrate polishing apparatus according to the example embodiment, FIG. 4 is a side view of the substrate polishing apparatus according to the example embodiment, and FIG. 5 is a block diagram of the substrate polishing apparatus according to the example embodiment.

Referring to FIGS. 1 to 5, a substrate polishing apparatus 1 may be used for a CMP process for a substrate. The substrate may be a silicon wafer used to manufacture a semiconductor device. However, the type of substrate is not limited thereto. For example, the substrate may include glass used for a flat panel display (FPD) device such as a liquid crystal display (LCD) and a plasma display panel (PDP).

The substrate polishing apparatus 1 may polish the substrate. The substrate polishing apparatus 1 may include a substrate carrier 10, a polishing unit U, a spray unit, a temperature sensor, a control unit, and a warning unit.

The polishing unit U may polish a polishing target surface of the substrate. The polishing unit U may include a polishing table T and a polishing pad P.

The polishing pad P may be connected to the polishing table T. For example, the polishing pad P may be attached to an upper portion of the polishing table T. The polishing table T may polish, in an orbital manner, the polishing target surface of the substrate being in contact with the polishing pad P while rotating about an axis. The polishing table T may adjust a position of the polishing pad P with respect to the ground surface while moving in a vertical direction. The polishing pad P may come into contact with the polishing target surface of the substrate and physically polish the polishing target surface of the substrate. The polishing pad P may be made of a material including polyurethane.

The substrate carrier 10 may grasp the substrate. The substrate carrier 10 may grasp a polishing target substrate by chucking and move the grasped substrate onto an upper portion of the polishing pad P. The substrate carrier 10 brings the substrate, which is transferred onto the upper portion of the polishing pad, into contact with the polishing pad P, thereby polishing the substrate. The substrate carrier 10 may determine a degree of polishing on the substrate by adjusting a frictional force between the substrate and the polishing pad P by pressing the substrate being in contact with the polishing pad P.

The substrate carrier 10 may include a carrier head 100, a membrane 101, and a retainer ring 102.

The carrier head 100 may adjust a position of the substrate. The carrier head 100 may receive power from the outside and rotate about an axis perpendicular to a surface of the polishing pad P. As the carrier head 100 rotates, the grasped substrate may be polished by being rotated while being in contact with the polishing pad P.

The carrier head 100 may move the substrate horizontally. For example, the carrier head 100 may perform translational motions in a first direction parallel to the surface of the polishing pad P and a second direction perpendicular to the first direction. The carrier head 100 may move the substrate on a plane parallel to the surface of the polishing pad P while performing the complex motions in the first and second directions. As a result, the substrate may be moved to a polishing position or removed from the polishing position as the carrier head 100 moves horizontally.

The carrier head 100 may move the substrate in the vertical direction relative to the ground surface. The carrier head 100 may move in the vertical direction relative to a substrate support part to perform chucking/dechucking on the substrate and move in the vertical direction relative to the polishing pad P to polish the substrate.

The membrane 101 may be connected to the carrier head 100 and define a pressure chamber C for applying a pressure to the substrate. The pressure to be applied to the substrate may be adjusted depending on a change in pressure in the pressure chamber C defined by the membrane 101. For example, a degree to which the substrate is pressed against the polishing pad P may be increased by increasing the pressure in the pressure chamber C in the state in which the substrate is in contact with the polishing pad P. The membrane 101 may include a bottom plate configured to define a bottom surface of the pressure chamber C, and a flap configured to define a sidewall of the pressure chamber C. The flap may be provided in plural, and the plurality of flaps has different radii with respect to a center of the bottom plate. A space between the adjacent flaps may be defined as the pressure chamber C. Different pressures may be applied to the pressure chambers C. The portions of the substrate, which correspond to the respective pressure chambers C, may be locally pressed by the pressures applied to the respective pressure chambers C.

The retainer ring 102 may be connected to the carrier head 100 and surround a grasped substrate W. The retainer ring 102 may prevent the substrate W from separating from a position at which the substrate W is grasped. For example, the retainer ring 102 may support a lateral side of the substrate W to prevent the substrate W from being separated from the substrate carrier 10 by vibration generated during the process of polishing the substrate W.

The retainer ring 102 may be connected directly to the carrier head 100 or indirectly to the carrier head 100 by means of a separate connection member. For example, the retainer ring 102 may be connected to the carrier head 100 and moved in the vertical direction relative to the substrate carrier 10 by a separate actuator.

The spray unit 11 may spray a fluid toward the substrate carrier 10 and the polishing pad P. For example, the spray unit 11 may spray a cooling fluid toward the substrate carrier 10. Since the spray unit 11 sprays the cooling fluid toward the substrate carrier 10, the substrate polishing apparatus 1 may maintain the temperature of the substrate carrier 10 within a predetermined range, thereby lengthening a replacement cycle that is performed when the substrate carrier 10 is abraded. Therefore, it is possible to reduce an economic loss caused by the replacement of the substrate carrier 10. In addition, the spray unit 11 may spray slurry toward the polishing pad P. Since the spray unit 11 supplies the slurry between the substrate and the polishing pad P, the substrate polishing apparatus 1 may not only polish the substrate by generating mechanical friction between slurry particles and surface protrusions of the polishing pad P, but also polish the surface of the substrate by using chemical reactions between compositions contained in the slurry.

The spray unit 11 may include a spray body 110, a spray member 111, a rotary member 112, a slurry supply member (not illustrated), and a leak sensor 113.

The spray body 110 may include a housing shape having an internal space. The spray body 110 may be disposed at one side of the substrate carrier 10 and provided above the polishing pad P. The cooling fluid to be sprayed by the spray member and the slurry to be sprayed toward the polishing pad P may be supplied into and stored in the spray body 110.

The spray member 111 may spray the fluid toward the substrate carrier 10. Specifically, the spray member 111 may spray the fluid toward the retainer ring 102. For example, the spray member 111 may be positioned at a lateral side of the spray body 110 and face the substrate carrier 10. The spray member 111 may be positioned at the lateral side of the spray body 110 and rotated upward or downward. In other words, the spray member 111 may spray the fluid toward a lateral side of the retainer ring 102 in a direction parallel to an upper surface of the polishing pad P. In addition, the spray member 111 may spray the fluid toward the lateral side of the retainer ring 102 at an angle of 30 degrees to 60 degrees with respect to the ground surface.

The spray unit 11 may further include a heat exchange member configured to adjust a temperature of the fluid to be sprayed. The fluid, of which the temperature has been adjusted to a particular temperature by the heat exchange member, may be sprayed by the spray member 111. The function of adjusting a temperature of the heat exchange member may be controlled by a control unit 13 to be described below.

Since the spray member 111 sprays the fluid toward the retainer ring 102, a surface temperature of the retainer ring 102 may be maintained within a predetermined range. With the above-mentioned operation, the substrate polishing apparatus 1 may reduce an abrasion rate of the retainer ring 102 by preventing overheating of the retainer ring 102.

The fluid sprayed by the spray member 111 may reach the polishing pad P along the substrate carrier 10. With the above-mentioned operation, the spray member 111 may cool not only the substrate carrier 10 but also the overheated polishing pad P, thereby maintaining the temperature of the polishing pad P within a predetermined range.

The rotary member 112 may rotate about the spray body 110 as a rotation axis. The rotary member 112 may be positioned at one side of the polishing pad and have a longitudinal direction perpendicular to the upper surface of the polishing pad P. That is, the spray body 110, which is operated by the rotary member 112, may rotate in a direction parallel to the upper surface of the polishing pad P.

The slurry supply member (not illustrated) may be connected to the spray body 110 and spray the slurry toward the polishing pad P. The slurry may be supplied between the substrate and the polishing pad P. The slurry may physically polish the surface of the substrate. Further, the slurry may chemically react with the material of the surface of the substrate and produce compound, thereby polishing the substrate. The heat exchanger may adjust a temperature of the slurry depending on a rate of polishing on the substrate. The slurry, of which the temperature has been adjusted to a predetermined temperature, may be sprayed toward the polishing pad P through the slurry supply member (not illustrated).

The leak sensor 113 may detect information on the spraying of the fluid. Specifically, the leak sensor 113 may measure the amount of fluid sprayed by the spray member and the time for which the fluid is sprayed.

The temperature sensor 12 may detect a change in temperature of the substrate carrier 10. For example, the temperature sensor 12 may be positioned at a lateral side of the retainer ring 102. In other words, the temperature sensor 12 may be provided in plural, and the plurality of temperature sensors 12 may be positioned at the lateral side of the retainer ring 102. The plurality of temperature sensors 12 may detect, for each point in time, a temperature of the retainer ring 102, which is raised by the frictional heat, and a temperature of the retainer ring 102 cooled by the fluid sprayed by the spray member 111. In addition, the temperature sensor 12 may be positioned on the polishing pad P and detect a change in temperature of the polishing pad P. The information on the temperatures of the substrate carrier 10 and the polishing pad P detected by the temperature sensor 12 may be used as reference information depending on which the control unit 13 to be described below performs control.

The control unit 13 may adjust the operation of the spray unit 11 on the basis of the information on the temperature detected by the temperature sensor 12. For example, the control unit 13 may adjust a spray angle of the spray unit 11, a temperature of the fluid to be sprayed, and the amount of fluid to be sprayed. That is, when a value of a temperature of the substrate carrier 10 detected by the temperature sensor 12 exceeds a reference overheating range, the control unit 13 may adjust a spray angle of the spray unit 11, a temperature of the fluid to be sprayed, and the amount of fluid to be sprayed on the basis of the value of the temperature and the point detected by the temperature sensor 12.

In addition, the control unit 13 may adjust the operations of the substrate carrier 10 and the polishing pad P on the basis of the information on the temperature detected by the temperature sensor 12. Therefore, when a value of a temperature of the substrate carrier 10 detected by the temperature sensor 12 exceeds a reference danger range instead of the reference overheating range, the control unit 13 may stop the substrate polishing process by stopping the operations of the substrate carrier 10 and the polishing pad P. As a result, it is possible to prevent a safety accident caused by the overheated substrate carrier 10 and prevent deterioration in yield of substrates.

The control unit 13 may adjust the amount of fluid to be sprayed by the spray unit 11 on the basis of the spray information detected by the leak sensor 113. With the above-mentioned operation, the control unit 13 may more efficiently maintain the temperature of the substrate carrier 10 by collectively considering a degree to which the fluid is sprayed by the spray unit 11, which is detected by the leak sensor 113, and the information on the temperature of the substrate carrier 10 detected by the temperature sensor 12.

The warning unit 14 may generate a warning signal when a value of a temperature of the substrate carrier 10 detected by the temperature sensor 12 exceeds the reference danger range. That is, the warning unit 14 may warn a user of a dangerous situation caused by overheating of the substrate carrier 10 through visual and auditory signals. With the above-mentioned function, it is possible to allow the user to immediately cope with a dangerous situation such as overheating of the substrate carrier 10.

While the example embodiments have been described above with reference to the limited drawings, the example embodiments may be variously and technically modified and altered from the disclosure by those skilled in the art. For example, appropriate results may be achieved even though the described technologies are performed in different orders from the described method, the described constituent elements such as the systems, the structures, the apparatuses, and the circuits are coupled or combined in different manners from the described method, and/or the constituent elements are substituted with or replaced by other constituent elements or equivalents.

Accordingly, other implements, other example embodiments, and equivalents to the appended claims are also included in the scope of the appended claims.

What is claimed is:

1. A substrate polishing apparatus comprising:
a substrate carrier configured to grasp and move a substrate;
a polishing pad configured to come into contact with a polishing target surface of the substrate and polish the polishing target surface of the substrate; and
a spray unit comprising a spray member configured to spray a fluid toward the substrate carrier.

2. The substrate polishing apparatus of claim 1, wherein the substrate carrier comprises:
a carrier head configured to adjust a position of the substrate;
a membrane connected to the carrier head and configured to define a pressure chamber for applying a pressure to the substrate; and
a retainer ring connected to the carrier head and configured to grasp the substrate.

3. The substrate polishing apparatus of claim 2, wherein the spray member sprays the fluid toward the retainer ring.

4. The substrate polishing apparatus of claim 3, wherein the spray member sprays the fluid toward a lateral side of the retainer ring in a direction parallel to an upper surface of the polishing pad.

5. The substrate polishing apparatus of claim 3, wherein the spray member sprays the fluid toward a lateral side of the retainer ring at an angle of 30 degrees to 60 degrees with respect to a ground surface.

6. The substrate polishing apparatus of claim 3, wherein the spray member sprays the fluid toward the retainer ring, such that a surface temperature of the retainer ring is maintained within a predetermined range.

7. The substrate polishing apparatus of claim 1, wherein the spray unit further comprises:
a spray body disposed at one side of the substrate carrier and positioned above the polishing pad; and
a rotary member configured to rotate the spray body about a rotation axis.

8. The substrate polishing apparatus of claim 7, wherein the spray member is positioned at a lateral side of the spray body and faces the substrate carrier.

9. The substrate polishing apparatus of claim 7, wherein the spray unit further comprises a slurry supply member connected to the spray body and configured to spray slurry toward the polishing pad.

10. The substrate polishing apparatus of claim 1, further comprising:
a temperature sensor configured to detect a change in temperature of the substrate carrier; and
a control unit configured to adjust an operation of the spray unit on the basis of information on a temperature detected by the temperature sensor.

11. The substrate polishing apparatus of claim 10, wherein the spray unit further comprises a leak sensor configured to detect a degree to which the fluid is sprayed.

12. The substrate polishing apparatus of claim 11, wherein the control unit adjusts the amount of fluid to be sprayed by the spray unit on the basis of spray information of the spray unit detected by the leak sensor.

13. The substrate polishing apparatus of claim 10, further comprising:
a warning unit configured to generate a warning signal when a value of a temperature of the substrate carrier detected by the temperature sensor exceeds a reference danger range.
